(19) United States
(12) Patent Application Publication
(10) Pub. No.: US 2024/0162144 A1
(43) Pub. Date: May 16, 2024

(54) SEMICONDUCTOR DEVICE

(71) Applicant: Renesas Electronics Corporation, Tokyo (JP)

(72) Inventors: Takayuki IGARASHI, Tokyo (JP); Yasutaka NAKASHIBA, Tokyo (JP); Tatsuo KASAOKA, Tokyo (JP)

(21) Appl. No.: 18/510,633

(22) Filed: Nov. 15, 2023

(30) Foreign Application Priority Data
Nov. 16, 2022 (JP) 2022-183257

(51) Int. Cl. H01L 23/522; H01L 23/00

(52) U.S. Cl. CPC H01L 23/5227; H01L 24/05; H01L 24/48; H01L 28/10; H01L 2224/04042; H01L 2224/05554; H01L 2224/48464; H01L 2924/30101

(57) ABSTRACT

A semiconductor device includes a semiconductor substrate, a multilayer wiring layer formed on the semiconductor substrate, a first wiring formed on the multilayer wiring layer and configured to be applied with a first potential, an upper inductor formed on the multilayer wiring layer and configured to be applied with a second potential different from the first potential, an inorganic insulating film formed on the multilayer wiring layer, the first wiring, and the upper inductor, and an organic insulating film formed on the inorganic insulating film and disposed so as to cover the inorganic insulating film located between the first wiring and the upper inductor in plan view. Here, between the first wiring and the upper inductor, an opening portion exposing a part of the upper surface of the inorganic insulating film is formed in the organic insulating film.

### CROSS-REFERENCE TO RELATED APPLICATIONS

The disclosure of Japanese Patent Application No. 2022-183257 filed on Nov. 16, 2022, including the specification, drawings and abstract is incorporated herein by reference in its entirety.

### BACKGROUND

The present disclosure relates to a semiconductor device and, more particularly, to a technique applicable to a semiconductor device capable of transmitting signals between different potentials using a pair of inductors coupled inductively.

There is a disclosed technique listed below.
[Patent Document 1] Japanese Unexamined Patent Application Publication No. 2011-82212

Patent Document 1 discloses a technique capable of increasing cross-sectional areas of coils without preventing miniaturization in order to reduce a series resistance which occupies most of the parasitic resistance components of the coils configuring the transformer.

### SUMMARY

For example, a transformer (digital isolator) that enables contactless signal transmission using a pair of inductors coupled inductively is known. Since this transformer allows signal transmission in a contactless state, the electrical noise from one circuit can be suppressed from adversely affecting the other circuit. In addition, in the transformer configured as described above, improving the breakdown voltage so as to enable contactless signal transmission between circuits having different potentials from each other.

In one embodiment, a semiconductor device includes a semiconductor substrate, a multilayer wiring layer formed on the semiconductor substrate; a first wiring formed on the multilayer wiring layer and configured to be applied with a first potential, an inductor formed on the multilayer wiring layer and configured to be applied with a second potential different from the first potential, an inorganic insulating film formed on the multilayer wiring layer, the first wiring and the inductor, and an organic insulating film formed on the inorganic insulating film and disposed so as to cover the inorganic insulating film located between the first wiring and the inductor in plan view. Here, between the first wiring and the inductor, an opening portion exposing a part of an upper surface of the inorganic insulating film is formed in the organic insulating film.

In one embodiment, a semiconductor device includes a semiconductor substrate, a multilayer wiring layer formed on the semiconductor substrate, a first inductor formed in the multilayer wiring layer and configured to be applied with a first potential, a second inductor formed on the multilayer wiring layer and configured to be applied with a second potential different from the first potential and configured to be magnetically connectable to the first inductor, an inorganic insulating film formed on the second inductor; and a mold resin formed to cover the inorganic insulating film.

One embodiment can improve the reliability of the semiconductor device.

### BRIEF DESCRIPTION OF THE DRAWINGS

FIG. 1 is a diagram showing a configuration example of a drive control unit that drives a load circuit such as a motor.

FIG. 2 is an explanatory diagram showing a signal transmission example.

FIG. 3 is a diagram showing a two-chip configuration.

FIG. 4 is a cross-sectional view showing a schematic configuration of a semiconductor device in a related art.

FIG. 5 is a plan view showing a semiconductor chip in the related art.

FIG. 6 is a diagram showing a configuration of a semiconductor device in a realization mode of a first embodiment.

FIG. 7 is a plan view showing a semiconductor chip in a first modified example of the first embodiment.

FIG. 8 is a plan view showing a semiconductor chip in a second modified example of the first embodiment.

FIG. 9 is a plan view showing a semiconductor chip in a third modified example of the first embodiment.

FIG. 10 is a plan view showing a semiconductor chip in a fourth modified example of the first embodiment.

FIG. 11 is a diagram showing a three-chip configuration.

FIG. 12 is a diagram showing a configuration of a semiconductor device in a realization mode of a second embodiment.

FIG. 13 is a diagram showing a configuration of a semiconductor device in a modified example.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

### Circuit Configuration

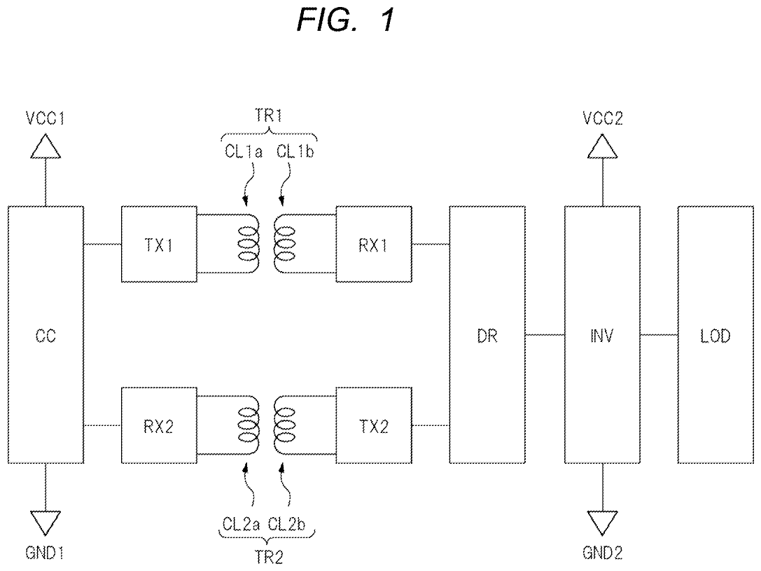

FIG. 1 is a diagram showing a configuration example of a drive control unit that drives the load circuit such as a motor. As shown in FIG. 1, the drive control unit includes a control circuit CC, a transformer TR1, a transformer TR2, a drive circuit DR, and an inverter INV, and is electrically connected to a load circuit LOD.

A transmitting circuit TX1 and a receiving circuit RX1 transmits a control signal outputted from the control circuit CC to the drive circuit DR. On the other hand, a transmitting circuit TX2 and a receiving circuit RX2 transmits a signal outputted from the drive circuit DR to the control circuit CC.

The control circuit CC has a function of controlling the drive circuit DR. The drive circuit DR operates the inverter INV that controls the load circuit LOD, based on control from the control circuit CC.

The control circuit CC is supplied with a power supply potential VCC1, and the control circuit CC is grounded by a ground potential GND1. On the other hand, the inverter INV is supplied with a power supply potential VCC2, and the inverter INV is grounded by a ground potential GND2. In this case, for example, the power supply potential VCC1 is smaller than the power supply potential VCC2 supplied to the inverter INV. In other words, the power supply potential VCC2 supplied to the inverter INV is greater than the power supply potential VCC1.

The transformer TR1 formed of a coil CL1a and a coil CL1b inductively (magnetically) coupled to each other is interposed between the transmitting circuit TX1 and the receiving circuit RX1. Thus, a signal can be transmitted from the transmitting circuit TX1 to the receiving circuit RX1 via the transformer TR1. Consequently, the drive circuit DR can receive the control signal outputted from the control circuit CC via the transformer TR1.

As described above, the transformer TR1 electrically isolated using the inductive coupling enables transmitting the control signal from the control circuit CC to the drive circuit DR while suppressing the transfer of the electric noise from the control circuit CC to the drive circuit DR. Therefore, a malfunction of the drive circuit DR caused by the superimposition of the electric noise on the control signal can be suppresses. Thus, the operation reliability of the semiconductor device can be improved.

The coil CL1a and the coil CL1b configuring the transformer TR1 each function as an inductor. The transformer TR1 function as a magnetically coupled element formed of the coil CL1a and the coil CL1b inductively coupled to each other.

Similarly, the transformer TR2 formed of a coil CL2b and a coil CL2a inductively coupled to each other is interposed between the transmitting circuit TX2 and the receiving circuit RX2. Thus, a signal can be transmitted from the transmitting circuit TX2 to the receiving circuit RX2 via the transformer TR2. Consequently, the control circuit CC can receive the signal outputted from the drive circuit DR via the transformer TR2.

As described above, the transformer TR2 electrically isolated using the inductive coupling enables transmitting the signal from the drive circuit DR to the control circuit CC while suppressing the transfer of the electric noise from the drive circuit DR to the control circuit CC. Therefore, a malfunction of the control circuit CC caused by the superimposition of the electric noise on the signal can be suppresses. Thus, the operation reliability of the semiconductor device can be improved.

The transformer TR1 is configured by the coil CL1a and the coil CL1b, and the coil CL1a and the coil CL1b are not connected by conductors but are magnetically coupled. Therefore, when a current flows in the coil CL1a, an induced electromotive force is generated in the coil CL1b in accordance with a change in the current, so that an induced current flows in the coil CL1b. In this case, the coil CL1a is a primary coil, and the coil CL1b is a secondary coil. As described above, the transformer TR1 utilizes the electromagnetic induction phenomenon occurring between the coil CL1a and the coil CL1b. That is, as a result of transmitting a signal from the transmitting circuit TX1 to the coil CL1a of the transformer TR1 to flow a current, the receiving circuit RX1 detects an induced current generated in the coil CL1b of the transformer TR1, so that the receiving circuit RX1 can receive a signal corresponding to the control signal outputted from the transmitting circuit TX1.

Similarly, the transformer TR2 is configured by the coil CL2a and the coil CL2b, and the coil CL2a and the coil CL2b are not connected by conductors but are magnetically coupled. Therefore, when a current flows in the coil CL2b, an induced electromotive force is generated in the coil CL2a in accordance with a change in the current, so that an induced current flows in the coil CL2a. As described above, as a result of transmitting a signal from the transmitting circuit TX2 to the coil CL2b of the transformer TR2 to flow a current, the receiving circuit RX2 detects an induced current generated in the coil CL2a of the transformer TR2, so that the receiving circuit RX2 can receive a signal corresponding to the control signal outputted from the transmitting circuit TX2.

A signal transmission is performed between the control circuit CC and the drive circuit DR using a path from the transmitting circuit TX1 to the receiving circuit RX1 via the transformer TR1 and using a path from the transmitting circuit TX2 to the receiving circuit RX2 via the transformer TR2. That is, the signal transmission can be performed between the control circuit CC and the drive circuit DR by the receiving circuit RX1 receiving the signal transmitted by the transmitting circuit TX1 and by the receiving circuit RX2 receiving the signal transmitted by the transmitting circuit TX2. As described above, the transformer TR1 is interposed in the signal transmission from the transmitting circuit TX1 to the receiving circuit RX1, and the transformer TR2 is interposed in the signal transmission from the transmitting circuit TX2 to the receiving circuit RX2. Thus, the drive circuit DR can drive the inverter INV operating the load circuit LOD in accordance with the signal transmitted from the control circuit CC.

The control circuit CC and the drive circuit DR have different reference potentials. That is, the reference potential is fixed to the ground potential GND1 in the control circuit CC, while the drive circuit DR is electrically connected to the inverter INV as shown in FIG. 1.

The inverter INV includes, for example, a high-side IGBT (Insulated Gate Bipolar Transistor) and a low-side IGBT. The drive circuit DR performs the on/off control of the high-side IGBT and the on/off control of the low-side IGBT in the inverter INV resulting in that the inverter INV can control the load circuit LOD.

Specifically, the drive circuit DR performs the on/off control of the high-side IGBT by controlling the potential applied to the gate electrode of the high-side IGBT. Similarly, the drive circuit DR performs the on/off control of the low-side IGBT by controlling the potential applied to the gate electrode of the low-side IGBT.

Here, for example, the on-control of the low-side IGBT is realized by applying “emitter potential (0 V)+threshold voltage (15 V)” to the gate electrode with reference to the emitter potential (0 V) of the low-side IGBT connected to the ground potential GND2.

On the other hand, for example, the off-control of the low-side IGBT is realized by applying an “emitter potential (0 V)” to the gate electrode with reference to the emitter potential (0 V) of the low-side IGBT connected to the ground potential GND2.

Therefore, the on/off control of the low-side IGBT is performed according to whether or not applying the threshold voltage (15 V) to the gate electrode with 0 V as a reference potential.

On the other hand, for example, the on-control of the high-side IGBT is performed by whether or not applying “reference potential+threshold voltage (15 V)” to the gate electrode with reference to the reference potential using the emitter potential of the high-side IGBT as a reference potential.

However, the emitter potential of the high-side IGBT is not fixed to the ground potential GND2 as is the emitter potential of the low-side IGBT. That is, the high-side IGBT and the low-side IGBT are connected in series between the power supply potential VCC2 and the ground potential GND2 in the inverter INV. In the inverter INV, when the high-side IGBT is set to on-state, the low-side IGBT is set to off-state, and when the high-side IGBT is set to off-state, the low-side IGBT is set to on-state.

Therefore, when the high-side IGBT is set to off-state, since the low-side IGBT is set to on-state, the emitter potential of the high-side IGBT becomes the ground potential GND2 due to the low-side IGBT set to on-state.

On the other hand, when the high-side IGBT is set to on-state, since the low-side IGBT is set to off-state, the emitter potential of the high-side IGBT becomes an IGBT bus voltage.

In this case, the on/off control of the high-side IGBT is performed by whether or not applying “reference potential+threshold voltage (15 V)” to the gate electrode with the emitter potential of the high-side IGBT as a reference potential.

As described above, the emitter potential of the high-side IGBT varies depending on whether the high-side IGBT is set to on-state or off-state. That is, the emitter potential of the high-side IGBT varies from the ground potential GND2 (0 V) to the power supply potential VCC2 (for example, 800 V). Therefore, in order to set the high-side IGBT to on-state, the “IGBT bus voltage (800 V)+threshold voltage (15 V)” needs to be applied to the gate electrode with the emitter potential of the high-side IGBT as a reference potential.

Therefore, the drive circuit DR that performs the on/off control of the high-side IGBT needs to detect the emitter potential of the high-side IGBT. Therefore, the drive circuit DR is configured to receive the emitter potential of the high-side IGBT. Consequently, the drive circuit DR receives the reference potential of 800 V, and the drive circuit DR controls to set the high-side IGBT to on-state by applying the threshold voltage of 15 V to the gate electrode of the high-side IGBT with respect to the reference potential of 800 V. Therefore, a high potential of the order of 800 V is applied to the drive circuit DR.

As described above, the drive control unit includes the control circuit CC that handles the low potential (several tens of volts) and the drive circuit DR that handles the high potential (several hundreds of volts). Therefore, the signal transmission between the control circuit CC and the drive circuit DR requires the signal transmission between the different potential circuits. In this regard, the signal transmission between the control circuit CC and the drive circuit DR is performed via the transformer TR1 and the transformer TR2, so that the signal can be transmitted between different potential circuits.

As described above, a large potential difference may be generated between the primary coil and the secondary coil in the transformer TR1 and the transformer TR2. Conversely, since a large potential difference may be generated, the primary coil and the secondary coil magnetically coupled to each other without being connected by a conductor are used for signal transmission. Therefore, in forming the transformer TR1, increasing the breakdown voltage between the coil CL1a and the coil CL1b as much as possible is required from the viewpoint of improving the operation reliability of the semiconductor device. Similarly, in forming the transformer TR2, increasing the breakdown voltage between the coil CL2b and the coil CL2a as much as possible is required from the viewpoint of improving the operation reliability of the semiconductor device.

### Signal Transmission Example

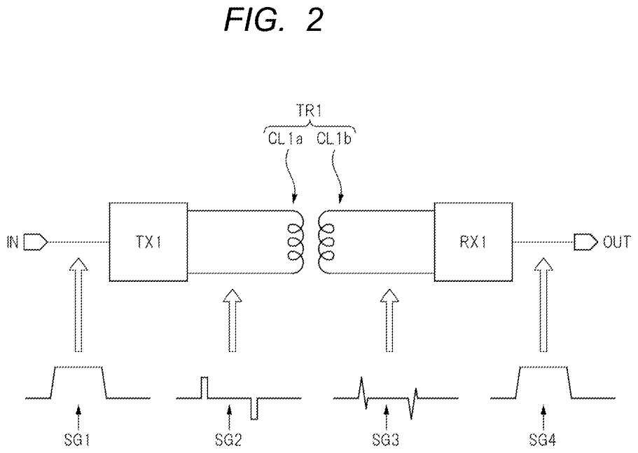

FIG. 2 is an explanatory diagram showing the signal transmission example.

In FIG. 2, the transmitting circuit TX1 extracts an edge part of a signal SG1 of the square wave inputted to the transmitting circuit TX1, generates a signal SG2 having a constant pulse width, and transmits the signal SG2 to the coil CL1a (primary coil) of the transformer TR1. When the current caused by the signal SG2 flows to the coil CL1a of the transformer TR1 (primary coil), a signal SG3 flows to the coil CL1b (secondary coil) of the transformer TR1 by the induced electromotive force. The receiving circuit RX1 amplifies the signal SG3 and further modulates into a square wave, and then the receiving circuit RX1 outputs a signal SG4 of the square wave. Thus, the receiving circuit RX1 can output the signal SG4 corresponding to the signal SG1 inputted to the transmitting circuit TX1. In this way, the signal can be transmitted from the transmitting circuit TX1 to the receiving circuit RX1. Similarly, the signal transmission can be transmitted from the transmitting circuit TX2 to the receiving circuit RX2.

### Two-Chip Configuration

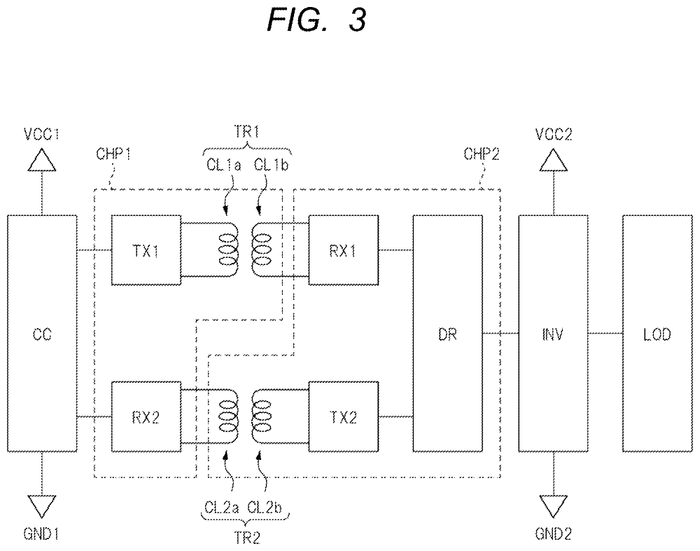

The transceiver circuit portion of the drive control unit described above, for example, is formed separately into two semiconductor chips. Specifically, FIG. 3 is a diagram showing the two-chip configuration. In FIG. 3, the transmitting circuit TX1, the transformer TR1, and the receiving circuit RX2 are formed in a semiconductor chip CHP1. On the other hand, the receiving circuit RX1, the drive circuit DR, the transmitting circuit TX2, and the transformer TR2 are formed in a semiconductor chip CHP2.

In such a two-chip configuration, for example, the transformer TR1 is formed on the same semiconductor chip CHP1 as the transmitting circuit TX1 and the receiving circuit RX2. Therefore, the transformer TR1, the transmitting circuit TX1, and the receiving circuit RX2 can be integrated. Similarly, the transformer TR2 is formed on the same semiconductor chip CHP2 as the drive circuit DR, the receiving circuit RX1, and the transmitting circuit TX2. Therefore, the transformer TR2, the drive circuit DR, the receiving circuit RX1, and the transmitting circuit TX2 can be integrated.

Here, for example, since the transmitting circuit TX1 and the receiving circuit RX2 are formed in the semiconductor chip CHP1, transistors configuring the transmitting circuit TX1 and the receiving circuit RX2 are formed in the semiconductor chip CHP1. Similarly, since the drive circuit DR, the receiving circuit RX1, and the transmitting circuit TX2 are formed in the semiconductor chip CHP2, transistors configuring the drive circuit DR, the receiving circuit RX1, and the transmitting circuit TX2 are also formed in the semiconductor chip CHP2. Therefore, in the semiconductor chip CHP1, the transformer TR1 and the transistors are formed together. Similarly, in the semiconductor chip CHP2, the transformer TR2 and the transistors are formed together.

### Explanation of Related Art

Hereinafter, the configuration of the semiconductor device in the related art premise a two-chip configuration will be described. The “related art” referred to in this specification is not a known technique, but is a technique having a problem found by the present inventors and is a technique which is a premise of the present invention.

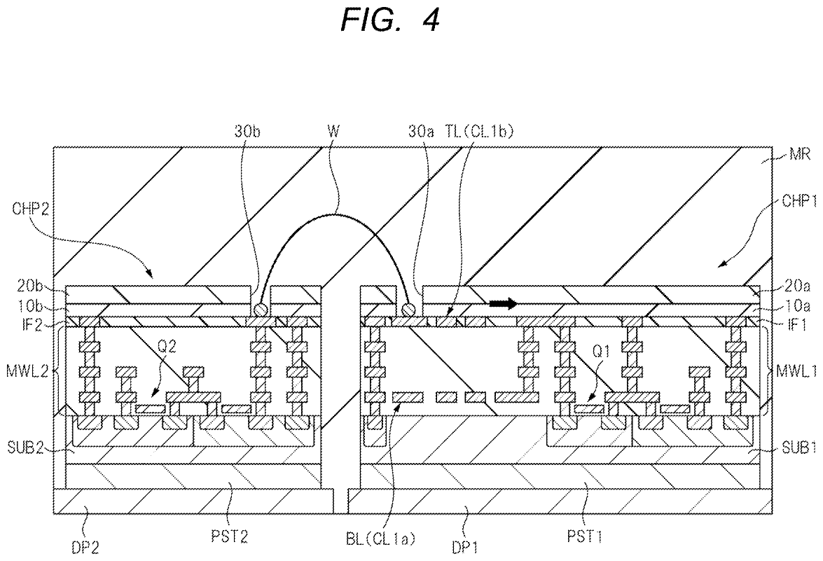

FIG. 4 is a cross-sectional view showing the schematic configuration of the semiconductor device in the related art.

In FIG. 4, the semiconductor device includes the semiconductor chip CHP1 and the semiconductor chip CHP2. That is, the semiconductor device in the related art shown in FIG. 4 has a two-chip configuration. The semiconductor chip CHP1 is mounted, for example, on a die pad DP1 that is a chip mounting portion via a conductive adhesive PST1. On the other hand, the semiconductor chip CHP2 is mounted, for example, on the a die pad DP2 which is a chip mounting portion via a conductive adhesive PST2.

Here, each of the die pad DP1 and the die pad DP2 is made of, for example, a copper material. Each of the conductive adhesive PST1 and the conductive adhesive PST2 is made of, for example, silver-paste or solder.

The transmitting circuit TX1, the receiving circuit RX2, and the transformer TR1 shown in FIG. 3 are formed in the semiconductor chip CHP1. As shown in FIG. 4, the semiconductor chip CHP1 includes a semiconductor substrate SUB1 and a multilayer wiring layer MWL1 formed on the semiconductor substrate SUB1.

The plurality of transistors Q1 is formed on the semiconductor substrate SUB1, and the multilayer wiring layer MWL1 is formed over the semiconductor substrate SUB1 in which the plurality of transistors Q1 is formed. In the multilayer wiring layer MWL1, a plurality of interlayer insulating films and a plurality of wirings are laminated. A wiring is formed in each layer of the multilayer wiring layer MWL1, and the wiring is electrically connected to the transistor Q1. The transistor Q1 and the wiring electrically connected to each other configure the transmitting circuit TX1 and the receiving circuit RX2.

In addition to wiring, the multilayer wiring layer MWL1 also includes a lower inductor BL (coil CL1a), which is a component of the transformer TR1. The lower inductor BL is formed of, for example, a spiral wiring.

Subsequently, as shown in FIG. 4, in the semiconductor chip CHP1, the wiring and an insulating film IF1 are formed on the multilayer wiring layer IF1 so as to be in contact with the uppermost layer of the multilayer wiring layer MWL1. Further, an upper inductor TL (coiled CL1b), which is a component of the transformer TR1, is formed on the multilayer wiring layer MWL1 so as to be in contact with the uppermost layer of the multilayer wiring layer MWL1.

An inorganic insulating film 10a is formed on the wiring including pads formed so as to be in contact with the uppermost layer of the multilayer wiring layer MWL1, the upper inductor TL, and the insulating film IF1, and an organic insulating film 20a is formed on the inorganic insulating film 10a. The organic insulating film 20a is formed in contact with the inorganic insulating film 10a.

Here, the inorganic insulating film 10a is formed of a silicon nitride film. On the other hand, the organic insulating film 20a is formed of a polyimide resin film.

In this case, a pad opening portion 30a is formed in the organic insulating film 20a and the inorganic insulating film 10a so as to penetrate through the organic insulating film 20a and the inorganic insulating film 10a in order to expose the surface of the pad which is a component of the upper inductor TL.

Next, the drive circuit DR, the receiving circuit RX1, and the transmitting circuit TX2 shown in FIG. 3 are formed in the semiconductor chip CHP2. As shown in FIG. 4, the semiconductor chip CHP2 includes a semiconductor substrate SUB2 and a multilayer wiring layer MWL2 formed on the semiconductor substrate SUB2.

The plurality of transistors Q2 is formed in the semiconductor substrate SUB2, and the multilayer wiring layer MWL2 is formed over the semiconductor substrate SUB2 in which the plurality of transistors Q2 is formed. In the multilayer wiring layer MWL2, a plurality of interlayer insulating films and a plurality of wirings are laminated. A wiring is formed in each layer of the multilayer wiring layer MWL2, and the wiring is electrically connected to the transistor Q2. The transistor Q2 and the wiring electrically connected to each other configure the drive circuit DR, the receiving circuit RX1, and the transmitting circuit TX2.

Then, the wiring including the pad and an insulating film IF2 are formed so as to be in contact with the uppermost layer of the multilayer wiring layer MWL2. Further, an inorganic insulating film 10b is formed on the wiring including the pad formed so as to be in contact with the uppermost layer of the multilayer wiring layer MWL2 and on the insulating film IF2, and an organic insulating film 20b is formed on the inorganic insulating film 10b. The organic insulating film 20b is formed in contact with the inorganic insulating film 10b.

Here, the inorganic insulating film 10b is formed of a silicon nitride film. On the other hand, the organic insulating film 20b is formed of a polyimide resin film. In this case, a pad opening portion 30b is formed in the organic insulating film 20b and the inorganic insulating film 10b so as to penetrate through the organic insulating film 20b and the inorganic insulating film 10b in order to expose the surface of the pad.

Next, as shown in FIG. 4, the upper inductor TL formed in the semiconductor chip CHP1 is electrically connected to a wiring (pad) disposed so as to be in contact with the uppermost layer of the multilayer wiring layer MWL2 of the semiconductor chip CHP2 via, for example, a bonding wire W. Specifically, as shown in FIG. 4, the pad, which is a component of the upper inductor TL exposed from the pad opening portion 30a, and the pad exposed from the pad opening portion 30b are connected via the bonding wire W. The upper inductor TL formed in the semiconductor chip CHP1 is formed of, for example, the pad and the spiral wiring connected to the pad.

The semiconductor chip CHP1 and the semiconductor chip CHP2 configured as described above are covered with, for example, a mold resin MR made of an epoxy resin. The semiconductor device of the two-chip configuration in the related art is configured as described above.

Further, the configuration of the semiconductor device in the related art will be described.

As shown in FIG. 4, the upper inductor TL that is a component of the transformer that performs non-contact communication between different potentials is formed in the semiconductor chip CHP1. In this case, the upper inductor TL is electrically connected to the wiring present in the multilayer wiring layer MWL2 formed in the semiconductor chip CHP2, and the second potential, which is a reference potential of about 800 V, is applied to the upper inductor TL. Specifically, the semiconductor device in the related art includes the semiconductor chip CHP2 having a circuit (second circuit) that applies the second potential to the upper inductor TL. The upper inductor TL formed in the semiconductor chip CHP1 is electrically connected to the circuit formed in the semiconductor chip CHP2 via the bonding wire W, which is an exemplary conductive member. Accordingly, the second potential outputted from the circuit formed in the semiconductor chip CHP2 is applied to the upper inductor TL.

Further, the lower inductor BL is formed in the semiconductor chip CHP1, and a circuit (first circuit) that applies a first potential, which is a reference potential of about 0 V, to the lower inductor BL. Accordingly, the first potential outputted from the circuit formed in the semiconductor chip CHP1 is applied to the lower inductor BL. Consequently, the second potential is applied to the upper inductor TL, while the first potential is applied to the lower inductor BL.

Here, the upper inductor TL is formed so as to be magnetically connectable to the lower inductor BL to which the first potential different from the second potential is applied in the thickness direction of the semiconductor chip CHP1. Specifically, the upper inductor TL is formed in contact with the uppermost layer of the multilayer wiring layer MWL1, while the lower inductor BL is formed in the multilayer wiring layer MWL1. Thus, the upper inductor TL and the lower inductor BL are configured to be magnetically connectable to each other.

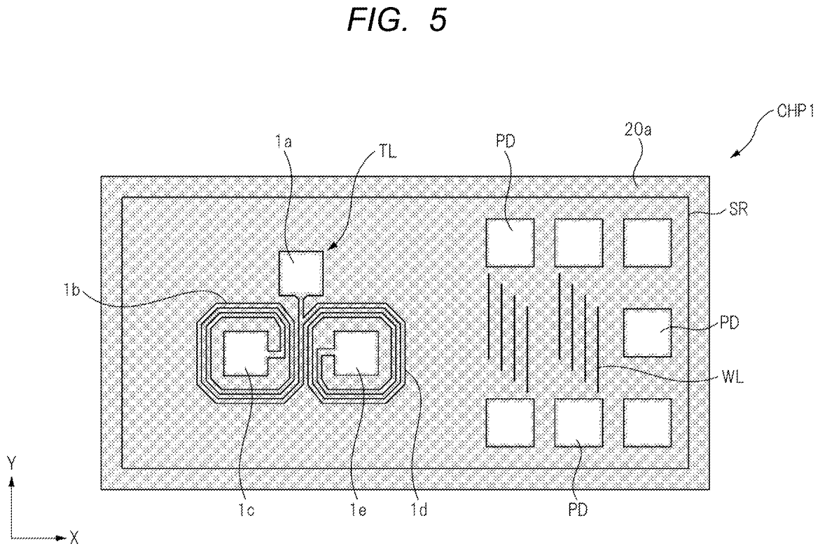

FIG. 5 is a plan view showing the semiconductor chip CHP1 in the related art.

In FIG. 5, a planar shape of the semiconductor chip CHP1 has a rectangular shape, and a sealing ring SR is formed at a peripheral edge portion of the semiconductor chip CHP1. The first potential is applied to the sealing ring SR. In plan view, the upper inductor TL is formed so as to be surrounded by the sealing ring SR. Here, the upper inductor TL is configured to include, for example, a center tap pad 1a, a spiral wiring 1b, a transpad 1c, a spiral wiring 1d, and a transpad 1e corresponding to a pair of differential wirings. Further, in plan view, a plurality of pads PD and a plurality of wirings WL are formed so as to be surrounded by the sealing ring SR. The plurality of pads PD and the plurality of wirings WL are disposed so as to be in contact with the uppermost layer of the multilayer wiring layer MWL1, for example, in FIG. 4.

Therefore, the upper inductor TL, the plurality of pads PD, and the plurality of wirings WL shown in FIG. 5 are formed so as to be in contact with the uppermost layer of the multilayer wiring layer MWL1. In other words, the upper inductor TL, the plurality of pads PD, and the plurality of wirings WL shown in FIG. 5 are disposed in the same layer. In the semiconductor chip CHP1, the pad (the center tap pad 1a, the transpad 1c, and the transpad 1e) and the plurality of pads PD are exposed from the organic insulating film 20a, while the organic insulating film 20a is formed so as to cover the wiring (the spiral wiring 1b and the spiral wiring 1d) of the upper inductor TL shown in FIG. and the plurality of wirings WL. In this case, the organic insulating film 20a is made of, for example, a polyimide resin film.

The plurality of pads PD include a pad electrically connected to the lower inductor BL (see FIG. 4) disposed under the upper inductor TL. That is, the lower inductor BL is disposed under the upper inductor TL, and the pad extracted from the lower inductor BL via a wiring is formed in the same layer as the upper inductor TL. The plurality of pads PD also include a pad electrically connected to the multilayer wiring disposed in the multilayer wiring layer MWL1 shown in FIG. 4, and the plurality of wirings WL include a wiring electrically connected to the wiring electrically connected to the lower inductor BL and the transistor Q2.

Here, for example, the second potential is applied to the upper inductor TL. On the other hand, the first potential is applied to the pad PD and the wiring WL connected to the lower inductor BL. That is, the reference potential (first potential) different from the reference potential (second potential) applied to the upper inductor TL is applied to the lower inductor BL that is paired with the upper inductor TL. As described above, the semiconductor chip CHP1 which is a component of the semiconductor device having a two-chip configuration in the related art is configured.

### Room for Improvement

Next, the room for improvement present in the related art will be described.

As described above, the second potential is applied to the upper inductor TL, while the first potential is applied to the pad (a part of the plurality of pads PD) electrically connected to the sealing ring SR or the lower inductor BL and a part of or the plurality of wirings WL. That is, as shown in FIG. 5, components having different potentials are disposed in the same layer on the multilayer wiring layer. Consequently, for example, a discharging phenomenon called “creeping discharge” may occur between the upper inductor TL to which the second potential is applied and the sealing ring SR to which the first potential is applied, between the upper inductor TL to which the second potential is applied and the pad to which the first potential is applied (a part of the plurality of pads PD), or between the upper inductor TL to which the second potential is applied and the wiring (a part of the plurality of wirings WL) to which the first potential is applied. Therefore, in the related art, a decrease in the breakdown voltage caused by the “creeping discharge” becomes apparent as a problem.

Here, the “creeping discharge” is defined as a discharge phenomenon in which a current flows between electrodes along the surface of an insulator when a high voltage is applied between a pair of electrodes disposed on the surface of the insulator.

As described above, in the related art, since components having different potentials are disposed on the multilayer wiring layer, the “creeping discharge” is likely to occur, and a decrease in the breakdown voltage caused by the “creeping discharge” becomes apparent. That is, in the related art, there is room for improvement from the viewpoint of improving the breakdown voltage by suppressing the “creeping discharge”.

In this regard, as a result of intensive studies on the “creeping discharge”, the present inventors have found new knowledge regarding “creeping discharge”, and based on this found new knowledge, have devised to overcome the room for improvement present in the related art. Hereinafter, the new knowledge regarding “creeping discharge” found by the present inventor will be described, and then a technical idea in the present embodiment, which is a contrivance made on the basis of the new knowledge, will be described.

### New Knowledge Regarding Creeping Discharge

Suppression of “creeping discharge” is a key issue in order to improve the reliability of the semiconductor device that enables the transmission of signals between different potentials by using a pair of magnetically coupled inductors. Therefore, analysis of “creeping discharge” and a countermeasure to suppress “creeping discharge” is required.

In this regard, the present inventors have newly found that a discharge current caused by “creeping discharge” flows along the interface between the inorganic insulating film 10a and the organic insulating film 20a, for example, as indicated by a thick arrow in FIG. 4.

Therefore, it is considered that a clue for suppressing “creeping discharge” exists in the inorganic insulating film 10a and the organic insulating film 20a. Therefore, the present inventors first focused on the organic insulating film 20a. In particular, since the organic insulating film 20a is formed of a polyimide resin film, attention was paid to the polyimide resin film to verify the effect of the polyimide resin film on “creeping discharge”. Specifically, the present inventors presumed that the moisture resistance of the polyimide resin film affects “creeping discharge”, and conducted verification results to confirm this.

For example, the semiconductor device was subjected to a high-temperature and high-humidity test (HAST), and it was confirmed that the breakdown voltage of the semiconductor device decreased over time in the high-temperature and high-humidity test. That is, it is presumed that the breakdown voltage of the semiconductor device decreases as the humidity of the polyimide resin film increases with the passage of time in the high-temperature and high-humidity test. In particular, when the polyimide resin film is subjected to baking treatment (heat treatment) after the high-temperature and high-humidity test, the breakdown voltage of the semiconductor device is restored, and it has been clarified that the breakdown voltage of the semiconductor device is related to the humidity of the polyimide resin film. That is, when the humidity of the polyimide resin film increases, “creeping discharge” tends to occur. It is considered that when the humidity of the polyimide resin film is increased, the dielectric constant of the polyimide resin film is apparently increased, and as a result, the electric flux density (D) inside the polyimide resin film is increased, and the breakdown voltage is decreased, so that “creeping discharge” is likely to occur. That is, there is a relationship of D=εE between the electric flux density (D) and the electric field (E), and as the dielectric constant (s) increases, the electric flux density (D) indicating the electric field in the polyimide resin film increases (dielectric effect). As a result, it can be considered that when the humidity of the polyimide resin film increases, the dielectric effect increases, and “creeping discharge” tends to occur. Furthermore, when a film having a high dielectric constant is disposed close to the pad, the above-described dielectric effect also occurs in the film, and as a result, it is considered that the breakdown voltage is reduced.

Specifically, the inorganic insulating film 10a is disposed close to the pad, and the inorganic insulating film 10a is formed of a silicon nitride film having a large dielectric constant. In this regard, as described above, there is a relationship of D=εE between the electric flux density (D) and the electric field (E), and as the dielectric constant (s) increases, the electric flux density (D) indicating the electric field in the silicon nitride film increases (dielectric effect). Consequently, it can be considered that if the inorganic insulating film 10a is formed of a silicon nitride film having a large dielectric constant, the dielectric effect is increased and “creeping discharge” is likely to occur.

From the above, the present inventors have obtained the following new knowledge. That is, the new knowledge found by the present inventors is that (1) creeping discharge is more likely to occur in a film having a high humidity, and (2) creeping discharge is more likely to occur in an insulating film having a high dielectric constant.

Therefore, based on the above-described knowledge which the present inventors has newly found, the present inventors have devised to overcome the room for improvement present in the related art. Hereinafter, the technical idea in the present embodiment to which the technique is applied will be described.

### FIRST EMBODIMENT

### Basic Idea in First Embodiment

The basic idea in the first embodiment is based on the above-described first knowledge that “creeping discharge” is more likely to occur in a film having a higher humidity. Specifically, the basic idea in the present first embodiment is a concept of forming an opening portion in an organic insulating film which is made of an insulating film having a high hygroscopic property and is present in a discharge path through which a discharge current of “creeping discharge” flows. More specifically, the basic idea of the present first embodiment is that an opening portion that exposes a part of the upper surface of the inorganic insulating film is formed in the organic insulating film disposed so as to cover the inorganic insulating film located between the first wiring configured to be applied with the first potential and the inductor configured to be applied with the second potential different from the first potential.

According to this basic idea, there is a region in which the organic insulating film having high hygroscopic property is removed between the first wiring configured to be applied with the first potential and the inductor configured to be applied with the second potential different from the first potential. As a consequence, in the region where the organic insulating film having high hygroscopic property is removed, the dielectric constant becomes low, so that “creeping discharge” is less likely to occur between the first wiring and the inductor in the removed region. Thus, according to the basic idea, generation of “creeping discharge” can be suppressed, so that the breakdown voltage of the semiconductor device can be improved.

### Realization Mode in First Embodiment

Next, the realization mode embodying the basic idea described above will be described.

### Configuration of Semiconductor Device

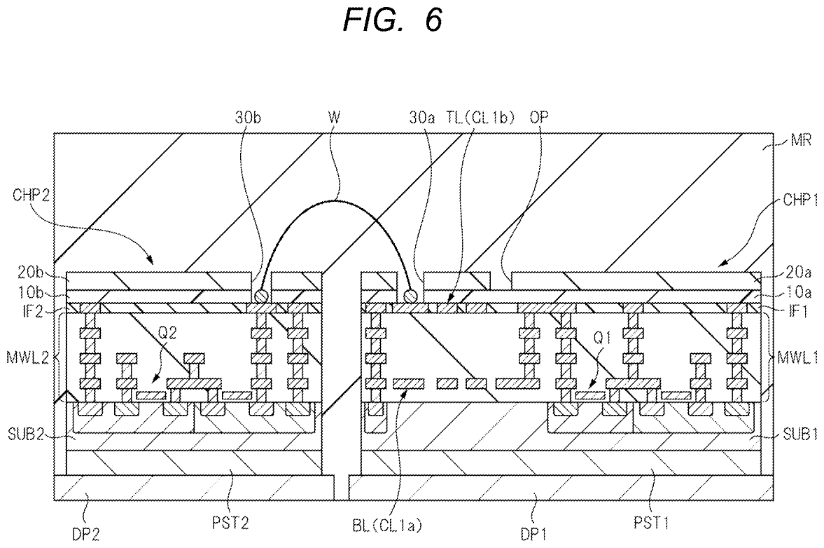

FIG. 6 is a cross-sectional view showing a schematic configuration of the semiconductor device in the realization mode.

In FIG. 6, the semiconductor device includes the semiconductor chip CHP1 and the semiconductor chip CHP2. That is, the semiconductor device in the realization mode shown in FIG. 6 has a two-chip configuration. The semiconductor chip CHP1 is mounted, for example, on the die pad DP1 that is a chip mounting portion via the conductive adhesive PST1. On the other hand, the semiconductor chip CHP2 is mounted, for example, on the die pad DP2 which is a chip mounting portion via the conductive adhesive PST2.

Here, each of the die pad DP1 and the die pad DP2 is made of, for example, a copper material. Each of the conductive adhesive PST1 and the conductive adhesive PST2 is made of, for example, silver-paste or solder.

The transmitting circuit TX1, the receiving circuit RX2, and the transformer TR1 shown in FIG. 3 are formed in the semiconductor chip CHP1. As shown in FIG. 6, the semiconductor chip CHP1 includes the semiconductor substrate SUB1 and the multilayer wiring layer MWL1 formed on the semiconductor substrate SUB1.

The plurality of transistors Q1 is formed on the semiconductor substrate SUB1, and the multilayer wiring layer MWL1 is formed over the semiconductor substrate SUB1 in which the plurality of transistors Q1 is formed. In the multilayer wiring layer MWL1, a plurality of interlayer insulating films and a plurality of wirings are laminated. A wiring is formed in each layer of the multilayer wiring layer MWL1, and the wiring is electrically connected to the transistor Q1. The transistor Q1 and the wiring electrically connected to each other configure the transmitting circuit TX1 and the receiving circuit RX2.

In addition to the wiring, the lower inductor BL (coil CL1a), which is a component of the transformer TR1 is formed in the multilayer wiring layer MWL1. The lower inductor BL is formed of, for example, a spiral wiring.

Subsequently, as shown in FIG. 6, the wiring (first wiring) and the insulating film IF1 are formed in the semiconductor chip CHP1 so as to be in contact with the uppermost layer of the multilayer wiring layer MWL1. Further, the upper inductor TL (coiled CL1b) that is a component of the transformer TR1 is formed so as to be in contact with the uppermost layer of the multilayer wiring layer MWL1. That is, the wiring (first wiring) and the upper inductor TL formed so as to be in contact with the uppermost layer of the multilayer wiring layer MWL1 are disposed in the same layer. The inorganic insulating film 10a is formed on the wiring (first wiring) including a pad formed so as to be in contact with the uppermost layer of the multilayer wiring layer MWL1, on the upper inductor TL, and on the insulating film IF1, and the organic insulating film 20a is formed on the inorganic insulating film 10a. Specifically, the organic insulating film 20a is disposed so as to cover the inorganic insulating film 10a located between the wiring (first wiring) and the upper inductor TL in plan view. The organic insulating film 20a is formed in contact with the inorganic insulating film 10a.

Here, the inorganic insulating film 10a is formed of a silicon nitride film. On the other hand, the organic insulating film 20a is formed of a polyimide resin film.

In this case, the pad opening portion 30a is formed in the organic insulating film 20a and the inorganic insulating film 10a so as to penetrate through the organic insulating film 20a and the inorganic insulating film 10a in order to expose the surface of the pad which is a component of the upper inductor TL. In the realization mode, as shown in FIG. 6, between the wiring (first wiring) and the upper inductor TL, the opening portion OP exposing a part of the upper surface of the inorganic insulating film 10a is formed in the organic insulating film 20a.

That is, in the realization mode, not only the pad opening portion 30a formed so as to penetrate through the organic insulating film 20a and the inorganic insulating film 10b in order to expose the pad connectable to the bonding wire W, but also an opening portion OP exposing a part of the upper surface of the inorganic insulating film 10a are formed. The opening portion OP differs from the pad opening portion 30a. That is, the inorganic insulating film 10a exposed from the opening portion OP is not formed with a through hole penetrating through the inorganic insulating film 10a unlike the pad opening portion 30a.

In the opening portion OP configured as described above, for example, it is desirable that the entire surface exposed from the opening portion OP is made of the inorganic insulating film 10a. That is, it is desirable that the inorganic insulating film 10a is exposed in the region exposed from the opening portion OP.

Next, the drive circuit DR, the receiving circuit RX1, and the transmitting circuit TX2 shown in FIG. 3 are formed in the semiconductor chip CHP2. As shown in FIG. 6, the semiconductor chip CHP2 includes the semiconductor substrate SUB2 and the multilayer wiring layer MWL2 formed on the semiconductor substrate SUB2.

The plurality of transistors Q2 is formed in the semiconductor substrate SUB2, and the multilayer wiring layer MWL2 is formed over the semiconductor substrate SUB2 in which the plurality of transistors Q2 is formed. In the multilayer wiring layer MWL2, a plurality of interlayer insulating films and a plurality of wirings are laminated. A wiring is formed in each layer of the multilayer wiring layer MWL2, and the wiring is electrically connected to the transistor Q2. The transistor Q2 and the wiring electrically connected to each other configure the drive circuit DR, the receiving circuit RX1, and the transmitting circuit TX2.

Then, the wiring including the pad and the insulating film IF2 are formed so as to be in contact with the uppermost layer of the multilayer wiring layer MWL2. Further, the inorganic insulating film 10b is formed on the wiring including the pads formed so as to be in contact with the uppermost layer of the multilayer wiring layer MWL2 and on the insulating film IF2, and the organic insulating film 20b is formed on the inorganic insulating film 10b. The organic insulating film 20b is formed in contact with the inorganic insulating film 10b.

Here, the inorganic insulating film 10b is formed of a silicon nitride film. On the other hand, the organic insulating film 20b is formed of a polyimide resin film. In this case, the pad opening portion 30b is formed in the organic insulating film 20b and the inorganic insulating film 10b so as to penetrate through the organic insulating film 20b and the inorganic insulating film 10b in order to expose the surface of the pad.

Subsequently, as shown in FIG. 6, the upper inductor TL formed in the semiconductor chip CHP1 is electrically connected to the wiring (pad) disposed so as to be in contact with the uppermost layer of the multilayer wiring layer MWL2 of the semiconductor chip CHP2 via, for example, the bonding wire W. Specifically, as shown in FIG. 6, the pad that is a component of the upper inductor TL exposed from the pad opening portion 30a and the pad that is exposed from the pad opening portion 30b are connected to each other via the bonding wire W. The upper inductor TL formed in the semiconductor chip CHP1 includes, for example, the pad and the spiral wiring connected to the pad. That is, the upper inductor TL includes the pad (first pad) connectable to the bonding wire W, and the wiring (second wiring) connected to the pad (first pad). In this case, the width of the wiring (first wiring) formed so as to be in contact with the uppermost layer of the multilayer wiring layer MWL1 is smaller than the width of the wiring (second wiring) configuring the upper inductor TL.

As shown in FIG. 6, the semiconductor chip CHP1 is formed with the upper inductor TL that is a component of the transformer that performs non-contact communication between different potentials. In this case, the upper inductor TL is electrically connected to the wiring present in the multilayer wiring layer MWL2 formed in the semiconductor chip CHP2, and the second potential, which is a reference potential of about 800 V, is applied to the upper inductor TL. Specifically, the semiconductor device in the realization mode includes the semiconductor chip CHP2 including a circuit (second circuit) that applies the second potential to the upper inductor TL. The upper inductor TL formed in the semiconductor chip CHP1 is electrically connected to the circuit formed in the semiconductor chip CHP2 via the bonding wire W, which is an exemplary conductive member. Accordingly, the second potential outputted from the circuit formed in the semiconductor chip CHP2 is applied to the upper inductor TL.

Further, the semiconductor chip CHP1 includes the lower inductor BL and the circuit (first circuit) that applies the first potential, which is a reference potential of about 0 V, to the lower inductor BL. Accordingly, the first potential outputted from the circuit formed in the semiconductor chip CHP1 is applied to the lower inductor BL. Consequently, the second potential is applied to the upper inductor TL, while the first potential is applied to the lower inductor BL. Further, the semiconductor chip CHP1 includes a plurality of wirings (first wiring) formed so as to be in contact with the uppermost layer of the multilayer wiring layer MWL1, and the plurality of wirings (first wiring) also include a wiring configured to be applied with the first potential.

Here, the upper inductor TL is formed so as to be magnetically connectable to the lower inductor BL to which the first potential different from the second potential is applied in the thickness direction of the semiconductor chip CHP1. Specifically, the upper inductor TL is formed in contact with the uppermost layer of the multilayer wiring layer MWL1, while the lower inductor BL is formed in the multilayer wiring layer MWL1. Thus, the upper inductor TL and the lower inductor BL are configured to be magnetically connectable to each other.

The semiconductor chip CHP1 and the semiconductor chip CHP2 configured as described above are covered with, for example, the mold resin MR made of an epoxy resin.

The semiconductor device of the two-chip configuration in the realization mode is configured as described above. That is, the semiconductor device of the two-chip configuration in the realization mode is configured to include the first wiring configured to be applied with the first potential, the circuit electrically connected to the first wiring, the upper inductor TL, the semiconductor chip CHP1 including the organic insulating film 20a, and the semiconductor chip CHP2 including the circuit configured to supply the second potential to the upper inductor TL.

### Features in Realization Mode

The feature points in the realization mode will be explained.

A feature point in the realization mode is, for example, as shown in FIG. 6, that, between the wiring (first wiring) disposed so as to be in contact with the uppermost layer of the multilayer upper surface layer MWL1 and the upper inductor TL disposed so as to be in contact with the uppermost layer of the multilayer wiring layer MWL1, the opening portion OP exposing a part of the upper surface of the inorganic insulating film 10a is formed in the organic insulating film 20a formed of the polyimide resin film. In other words, the feature point of the realization mode is that the opening portion OP is formed in the organic insulating film 20a made of a polyimide resin film disposed so as to cover the inorganic insulating film 10a located between the wiring (first wiring) configured to be applied with the first potential and the upper inductor TL configured to be applied with the second potential.

Accordingly, it is possible to suppress “creeping discharge” occurring between the wiring (first wiring) to which the different potential is applied and the upper inductor TL. This is because the opening portion OP is formed in the polyimide resin film formed between the wiring (first wiring) and the upper inductor TL, and thus there is a region (opening portion OP) in which the polyimide resin film having high hygroscopic property is removed in the discharge path of the “creeping discharge”. That is, the region (opening portion OP) from which the polyimide resin film having high hygroscopic property is removed is present in the discharge path of the “creeping discharge”, and consequently, the “creeping discharge” is blocked by the opening portion OP. Therefore, according to the realization mode, the generation of “creeping discharge” can be suppressed, so that the breakdown voltage of the semiconductor device can be improved.

Specifically, the polyimide resin film is removed in the opening portion OP, and the mold resin MR made of an epoxy resin is buried. Here, the dielectric constant (relative dielectric constant) of the polyimide resin is “4.8” and the hygroscopic property of the polyimide resin is “1.20”, while the dielectric constant (relative dielectric constant) of the epoxy resin is “3.5”, and the hygroscopic property of the epoxy resin is “0.45%”. Therefore, according to the realization mode, the opening portion OP in which the epoxy resin having a dielectric constant (relative dielectric constant) smaller than that of the polyimide resin film and a low hygroscopic property is buried is present in the discharge path of the “creeping discharge”. Therefore, considering that “creeping discharge” is less likely to occur as the dielectric constant (relative dielectric constant) and hygroscopic property of the film are smaller, it can be seen that “creeping discharge” can be suppressed according to the realization mode having the above-described feature points.

In this regard, it is conceivable to remove the entire polyimide resin film as long as “creeping discharge” is promoted by the presence of the polyimide resin film having high hygroscopic property.

However, in the semiconductor device having a two-chip configuration, the entire polyimide resin film cannot be removed. The reason for this will be described below.

For example, in FIG. 6, the organic insulating film 20a made of a polyimide resin film is formed to suppress “filler attack” caused by the mold resin MR formed so as to cover the organic insulating film 20a. That is, in the mold resin MR, fillers are added to the epoxy resin in order to improve the thermal conductivity. As the filler, a sharp crushing filler is usually used. Therefore, when the organic insulating film 20a made of a polyimide resin film is not present, the sharp crushing filler breaks through the inorganic insulating film 10a and damages wiring. This phenomenon is called “filler attack”. That is, the organic insulating film 20a formed of the polyimide resin film serves to suppress “filler attack” caused by the crushing filler contained in the mold resin MR. In particular, the “filler attack” becomes apparent in the fine wiring. In this regard, in the semiconductor chip CHP1 shown in FIG. 6, not only the upper inductor TL and the lower inductor BL but also the transistor Q1 and the multilayer wiring are formed. In this case, since the multilayer wiring connected to the transistor Q1 is a fine wiring, if the entire organic insulating film 20a made of a polyimide resin film is removed, the effect of “filler attack” is greatly affected. That is, in the semiconductor device having a two-chip configuration as shown in FIG. 6, since the fine wiring is also disposed together with the upper inductor TL, the entire organic insulating film 20a made of the polyimide resin film cannot be removed from the viewpoint of suppressing “filler attack” on the fine wiring.

Therefore, in the realization mode, in order to suppress the “creeping discharge” caused by the polyimide resin film having high hygroscopic property while leaving the organic insulating film 20a made of the polyimide resin film, the opening portion OP exposing a part of the upper surface of the inorganic insulating film 10a is formed in the organic insulating film 20a made of the polyimide resin film between the first wiring and the upper inductor TL serving as the discharge path. Thus, according to the realization mode, the opening portion OP formed in the polyimide resin film can suppress the occurrence of “creeping discharge” while suppressing the “filler attack” in the fine wiring by the polyimide resin film.

### First Modified Example in First Embodiment

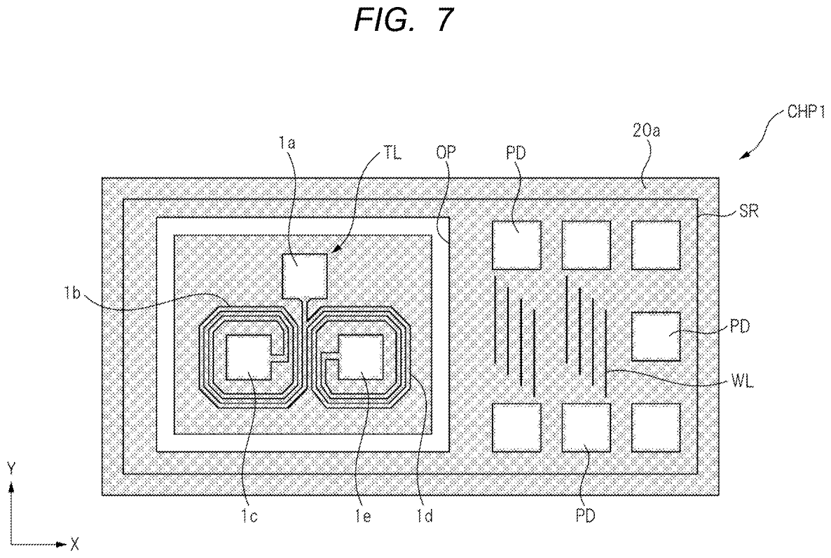

FIG. 7 is a plan view showing the semiconductor chip CHP1 in the present first modified example.

In FIG. 7, a planar shape of the semiconductor chip CHP1 has a rectangular shape, and the sealing ring SR is formed at a peripheral edge portion of the semiconductor chip CHP1. The first potential (about 0 V) is applied to the sealing ring SR. In plan view, the upper inductor TL is formed so as to be surrounded by the sealing ring SR. Here, the upper inductor TL is configured to include, for example, the center tap pad 1a, the spiral wiring 1b, the transpad 1c, the spiral wiring 1d, and the transpad 1e corresponding to a pair of differential wirings. Further, in plan view, the plurality of pads PD and the plurality of wirings WL are formed so as to be surrounded by the sealing ring SR. The plurality of pads PD and the plurality of wirings WL are disposed in contact with the uppermost layer of the multilayer wiring layer MWL1, for example, in FIG. 6.

Therefore, the upper inductor TL, the plurality of pads PD, and the plurality of wirings WL shown in FIG. 7 are formed so as to be in contact with the uppermost layer of the multilayer wiring layer MWL1. In other words, the upper inductor TL, the plurality of pads PD, and the plurality of wirings WL shown in FIG. 7 are disposed in the same layer. In the semiconductor chip CHP1, the pad (the center tap pad 1a, the transpad 1c, and the transpad 1e) and the plurality of pads PD are exposed from the organic insulating film 20a while the organic insulating film 20a is formed so as to cover the wiring (the spiral wiring 1b and the spiral wiring 1d) of the upper inductor TL and the plurality of wirings WL shown in FIG. 7. In this case, the organic insulating film 20a is made of, for example, a polyimide resin film.

The plurality of pads PD includes a pad electrically connected to the lower inductor BL (see FIG. 6) disposed under the upper inductor TL. That is, the lower inductor BL is disposed under the upper inductor TL, and the pad extracted from the lower inductor BL is formed in the same layer as the upper inductor TL. The plurality of pads PD also include the pad electrically connected to the multilayer wiring disposed in the multilayer wiring layer MWL1 shown in FIG. 6, and the plurality of wirings WL include the wiring electrically connected to the wiring electrically connected to the lower inductor BL and the transistor Q2. Here, the second potential (about 800 V) is applied to the upper inductor TL. On the other hand, the first potential (about 0 V) is applied to the pad PD and the wiring WL connected to the lower inductor BL. Therefore, there is a possibility that “creeping discharge” occurs between the upper inductor TL to which the second potential is applied and the pad PD and the wiring WL to which the first potential is applied. In this regard, in the present first modified example, as shown in FIG. 7, the opening portion OP is formed so as to surround the upper inductor TL in a planar manner. Accordingly, it is possible to effectively suppress “creeping discharge” between the upper inductor TL to which the second potential is applied and the sealing ring SR to which the first potential is applied, between the upper inductor TL to which the second potential is applied and the pad (a part of the plurality of pads PD) to which the first potential is applied, or between the upper inductor TL to which the second potential is applied and the wiring (a part of the plurality of wirings WL) to which the first potential is applied.

### Second Modified Example in First Embodiment

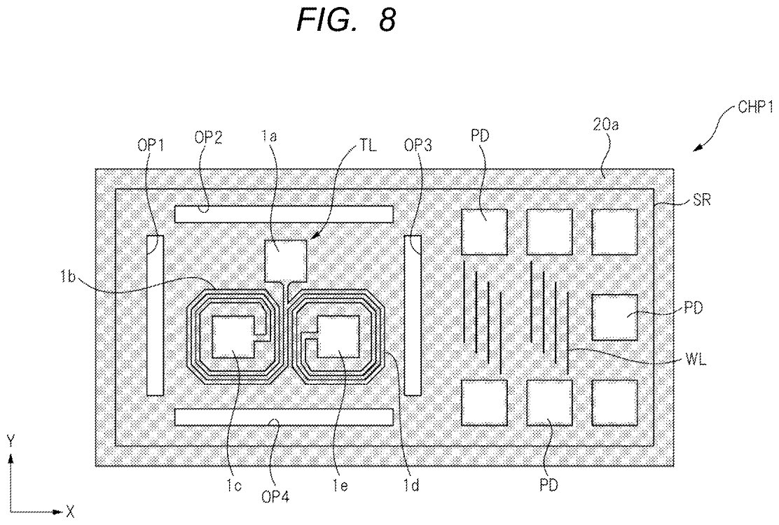

In the first modified example, an example has been described in which the opening portion OP is formed so as to surround the upper inductor TL in a planar manner, but the opening portion OP may not be formed so as to completely surround the upper inductor TL. Specifically, the opening portion may be formed as shown in FIG. 8.

FIG. 8 is a plan view showing the semiconductor chip CHP1 in the present second modified example.

In FIG. 8, the opening portion includes a first opening portion OP1 extending in the Y direction (first direction), a second opening portion OP2 extending in the X direction (second direction) intersecting with the Y direction, a third opening portion OP3 extending in the Y direction and facing the first opening portion OP1, and a fourth opening portion OP4 extending in the X direction and facing the second opening portion OP2. Here, the upper inductor TL is disposed between the first opening portion OP1 and the third opening portion OP3 in plan view, and the upper inductor TL is disposed between the second opening portion OP2 and the fourth opening portion OP4 in plan view.

Then, the first opening portion OP1 and the second opening portion OP2 are spaced apart from each other in plan view, the first opening portion OP1 and the fourth opening portion OP4 are spaced apart from each other in plan view, and the third opening portion OP3 and the second opening portion OP2 are spaced apart from each other in plan view, and the third opening portion OP3 and the fourth opening portion OP4 are spaced apart from each other in plan view. The opening portion configured in this way (first opening portion OP1, second opening portion OP2, third opening portion OP3 and fourth opening portion OP4) can effectively suppress the “creeping discharge” between the upper inductor TL to which the second potential is applied and the sealing ring SR to which the first potential is applied, between the upper inductor TL to which the second potential is applied and the pad (a part of the plurality of pads PD) to which the first potential is applied, or between the upper inductor TL to which the second potential is applied and the wiring (a part of the plurality of wirings WL) to which the first potential is applied.

### Third Modified Example in First Embodiment

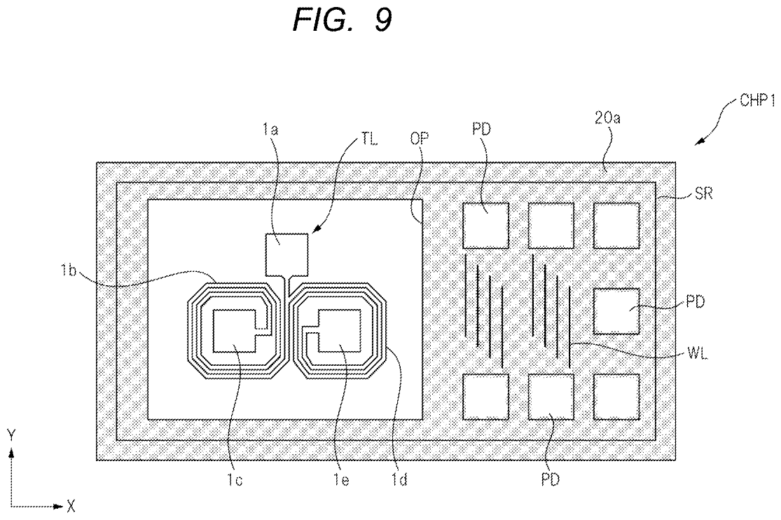

FIG. 9 is a plan view showing the semiconductor chip CHP1 in the present third modified example.

In FIG. 9, the opening portion OP is formed in the organic insulating film 20a formed of a polyimide resin film, and the opening portion OP is configured to include the upper inductor TL. In other words, the opening portion OP is formed to expose the upper inductor TL.

Accordingly, according to the present third modified example, it is possible to effectively suppress “creeping discharge” between the upper inductor TL to which the second potential is applied and the sealing ring SR to which the first potential is applied, between the upper inductor TL to which the second potential is applied and the pad (a part of the plurality of pads PD) to which the first potential is applied, or between the upper inductor TL to which the second potential is applied and the wiring (a part of the plurality of wirings WL) to which the first potential is applied.

Here, the fact that the upper inductor TL is included in the opening portion OP means that there is no organic insulating film 20a made of a polyimide resin film covering the upper inductor TL. Since the upper inductor TL has the spiral wiring 1b and the spiral wiring 1d while there is no organic insulating film 20a covering the upper inductor TL, the spiral wiring 1b and the spiral wiring 1d configuring the upper inductor TL may be damaged by “filler attack” caused by the crushing fillers included in the mold resin.

In this regard, a wiring that is susceptible to adverse effects by “filler attack” is a fine wiring. In contrast, the spiral wiring 1b and the spiral wiring 1d configuring the upper inductor TL are made of a wide wiring in order to reduce the parasitic resistance. That is, the width of the spiral wiring 1b and the spiral wiring 1d configuring the upper inductor TL is greater than the width of the first wiring which is the fine wiring.

Such a wide wiring is less susceptible to “filler attack”. Therefore, even if the opening portion OP is formed to include the upper inductor TL as in the present third modified example, adverse effects caused by the “filler attack” caused by the crushing filler contained in the mold resin are small. Further, for example, a “filler attack” can be suppressed by using, as the filler contained in the mold resin, not a sharp]crushing filler but a blunt spherical filler. As described above, also in the present third modified example, it is possible to effectively suppress “creeping discharge” between the upper inductor TL to which the second potential is applied and the sealing ring SR to which the first potential is applied, between the upper inductor TL to which the second potential is applied and the pad (a part of the plurality of pads PD) to which the first potential is applied, or between the upper inductor TL to which the second potential is applied and the wiring (a part of the plurality of wirings WL) to which the first potential is applied.

### Fourth Modified Example in First Embodiment

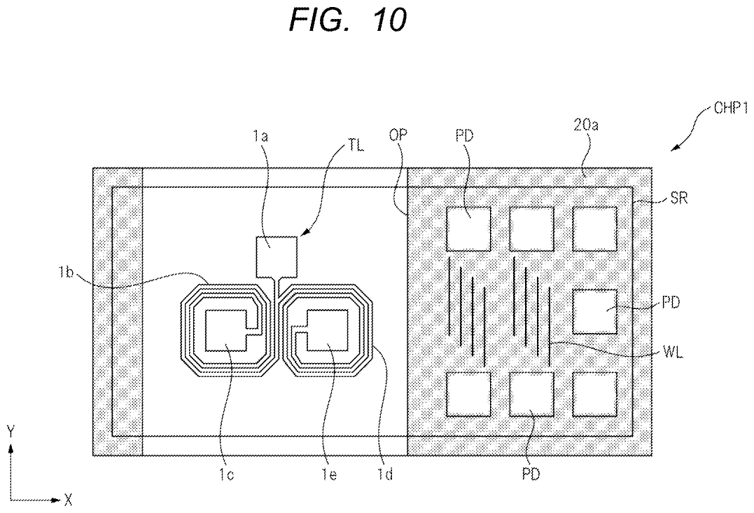

FIG. 10 is a plan view showing the semiconductor chip CHP1 in the present fourth modified example.

In FIG. 10, the opening portion OP is formed in the organic insulating film 20a formed of a polyimide resin film. The opening portion OP is formed so as to include the upper inductor TL and a part of the sealing ring SR (first wiring). In other words, the opening portion OP is formed so as to expose the upper inductor TL and a part of the sealing ring SR (first wiring) and reach the chip-end in the Y-direction. Thus, according to the present fourth modified example, “creeping discharge” between the upper inductor TL and the sealing ring SR in the Y direction can be effectively suppressed because there is no organic insulating film 20a made of a polyimide resin film between the upper inductor TL and the sealing ring SR in the Y direction.

### SECOND EMBODIMENT

### Three-Chip Configuration

In the semiconductor device in the first embodiment described above, a two-chip configuration is adopted. However, in the two-chip configuration, for example, the transformer TR1, the transmitting circuit TX1, and the receiving circuit RX2 need to be formed on one semiconductor chip resulting in complicating the manufacturing process of the semiconductor chip CHP1. Alternatively, in the two-chip configuration, for example, the transformer TR2, the drive circuit DR, the receiving circuit RX1, and the transmitting circuit TX2 need to be formed on one semiconductor chip resulting in complicating the manufacturing process of the semiconductor chip CHP2. As a consequence, the manufacturing costs of the semiconductor chip CHP1 and the semiconductor chip CHP2 may increase.

Therefore, it has been studied to realize the above-described semiconductor device not in the two-chip configuration but in the three-chip configuration. Hereinafter, a novel three-chip configuration will be described.

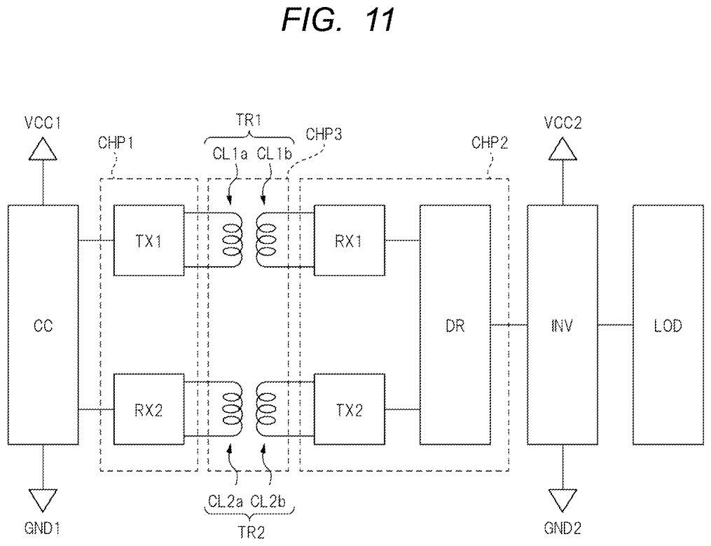

FIG. 11 is a diagram showing a three-chip configuration.

In FIG. 11, the transmitting circuit TX1 and the receiving circuit RX2 are formed in the semiconductor chip CHP1. In addition, the drive circuit DR, the receiving circuit RX1, and the transmitting circuit TX2 are formed in the semiconductor chip CHP2. On the other hand, the transformer TR1 and the transformer TR2 are formed in a semiconductor chip CHP3.

Thus, in the three-chip configuration, only the transformer TR1 and the transformer TR2 are formed in the semiconductor chip CHP3. That is, in the three-chip configuration, the semiconductor chip CHP3 can be used regardless of the configuration of the semiconductor chip CHP1 and the semiconductor chip CHP2. As a result, according to the three-chip configuration, the usable variation of the semiconductor chip CHP1 and the semiconductor chip CHP2 can be increased. In other words, the versatility of the semiconductor chip CHP3 in which the transformer TR1 and the transformer TR2 are formed can be improved. Further, since the semiconductor chip CHP3 in which the transformer TR1 and the transformer TR2 are formed does not include a transistor, the semiconductor chip CHP3 can be formed only by wiring process, and thus the manufacturing process can be simplified. Therefore, according to the three-chip configuration, the manufacturing cost can be reduced.

In the following description, the semiconductor chip CHP3 in which the transformer TR1 and the transformer TR2 are formed is sometimes referred to as a “transformer chip”.

### Basic Idea in Second Embodiment

The basic idea of the present second embodiment is based on the above-described first knowledge that “creeping discharge” is more likely to occur in a film having a higher humidity. That is, considering that “creeping discharge” is likely to occur when a film having high hygroscopic property is formed, the basic idea in the present second embodiment is that an organic insulating film made of an insulating film having high hygroscopic property is not formed in the “transformer chip”. In other words, the basic idea of the present second embodiment is to configure a semiconductor device including a “transformer chip” such that the upper surface of the inorganic insulating film is in direct contact with the mold resin without forming an organic insulating film made of the insulating film having high hygroscopic property on the inorganic insulating film.

Specifically, the “transformer chip” includes the semiconductor substrate, the multilayer wiring layer formed on the semiconductor substrate, the lower inductor formed in the multilayer wiring layer and configured to be applied with the first potential, the upper inductor formed on the multilayer wiring layer and configured to be applied with the second potential different from the first potential, and configured to be magnetically connectable with the lower inductor, and the inorganic insulating film formed on the upper inductor. It is assumed that the “transformer chip” is sealed with a mold resin so as to cover the inorganic insulating film. In this case, the basic idea of the present second embodiment is that the upper surface of the inorganic insulating film is in direct contact with the mold resin.

According to this basic idea, since the organic insulating film made of a film having high hygroscopic property, which is likely to cause “creeping discharge”, is not formed in the “transformer chip”, generation of “creeping discharge” can be suppressed. Therefore, according to this basic idea, the breakdown voltage of the semiconductor device can be improved.

### Realization Mode in Second Embodiment

Next, the realization mode embodying the basic idea described above will be described.

### Configuration of Semiconductor Device

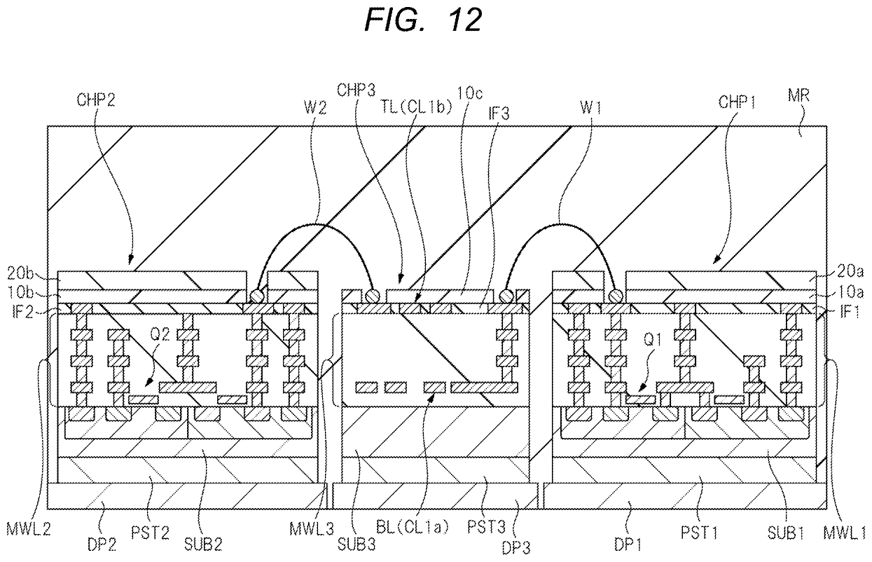

FIG. 12 is a cross-sectional view showing a schematic configuration of the semiconductor device in the realization mode.

In FIG. 12, the semiconductor device includes the semiconductor chip CHP1, the semiconductor chip CHP2, and the semiconductor chip CHP3. That is, the semiconductor device in the realization mode shown in FIG. 12 has a three-chip configuration.

The semiconductor chip CHP1 is mounted, for example, on the die pad DP1 that is a chip mounting portion via the conductive adhesive PST1. On the other hand, the semiconductor chip CHP2 is mounted, for example, on the die pad DP2 which is a chip mounting portion via the conductive adhesive PST2. Further, the semiconductor chip CHP3 is mounted, for example, on a die pad DP3 which is a chip mounting portion via a conductive adhesive PST3.

Here, the die pad DP1, the die pad DP2, and the die pad DP3 are made of, for example, copper material. The conductive adhesive PST1, the conductive adhesive PST2, and the conductive adhesive PST3 are made of, for example, silver-paste or solder.

The transmitting circuit TX1 and the receiving circuit RX2 shown in FIG. 11 are formed in the semiconductor chip CHP1. As shown in FIG. 12, the semiconductor chip CHP1 includes the semiconductor substrate SUB1 and the multilayer wiring layer MWL1 formed on the semiconductor substrate SUB1.

The plurality of transistors Q1 is formed on the semiconductor substrate SUB1, and the multilayer wiring layer MWL1 is formed over the semiconductor substrate SUB1 in which the plurality of transistors Q1 is formed. In the multilayer wiring layer MWL1, a plurality of interlayer insulating films and a plurality of wirings are laminated. A wiring is formed in each layer of the multilayer wiring layer MWL1, and the wiring is electrically connected to the transistor Q1. The transistor Q1 and the wiring electrically connected to each other configure the transmitting circuit TX1 and the receiving circuit RX2.

Subsequently, as shown in FIG. 12, in the semiconductor chip CHP1, the wiring and the insulating film IF1 are formed so as to be in contact with the uppermost layer of the multilayer wiring layer MWL1. The inorganic insulating film 10a is formed on the wiring including pads formed so as to be in contact with the uppermost layer of the multilayer wiring layer MWL1 and the insulating film IF1, and the organic insulating film 20a is formed on the inorganic insulating film 10a. Here, the inorganic insulating film 10a is formed of a silicon nitride film. On the other hand, the organic insulating film 20a is formed of a polyimide resin film.

Next, the transmitting circuit TX2, the receiving circuit RX1, and the drive circuit DR shown in FIG. 11 are formed in the semiconductor chip CHP2. As shown in FIG. 12, the semiconductor chip CHP2 includes the semiconductor substrate SUB2 and the multilayer wiring layer MWL2 formed on the semiconductor substrate SUB2.

The plurality of transistors Q2 is formed in the semiconductor substrate SUB2, and the multilayer wiring layer MWL2 is formed over the semiconductor substrate SUB2 in which the plurality of transistors Q2 is formed. In the multilayer wiring layer MWL2, a plurality of interlayer insulating films and a plurality of wirings are laminated. A wiring is formed in each layer of the multilayer wiring layer MWL2, and the wiring is electrically connected to the transistor Q2. The transistor Q2 and the wiring electrically connected to each other configure the transmitting circuit TX2, the receiving circuit RX1, and the drive circuit DR.

Subsequently, as shown in FIG. 12, in the semiconductor chip CHP2, the wiring and the insulating film IF2 are formed so as to be in contact with the uppermost layer of the multilayer wiring layer MWL2. The inorganic insulating film 10b is formed on the wiring including pads formed so as to be in contact with the uppermost layer of the multilayer wiring layer MWL2 and the insulating film IF2, and the organic insulating film 20b is formed on the inorganic insulating film 10b. Here, the inorganic insulating film 10b is formed of a silicon nitride film. On the other hand, the organic insulating film 20b is formed of a polyimide resin film.

Next, the transformer TR1 and the transformer TR2 shown in FIG. 11 are formed in the semiconductor chip CHP3 (“transformer chip”). As shown in FIG. 12, the semiconductor chip CHP3 includes a semiconductor substrate SUB3 and a multilayer wiring layer MWL3 formed on the semiconductor substrate SUB3. In addition to the wiring, the multilayer wiring layer MWL3 includes the lower inductor BL (coiled CL1a), which is a component of the transformer TR1. The lower inductor BL is formed of, for example, a spiral wiring.

Then, as shown in FIG. 12, in the semiconductor chip CHP3, the wiring and an insulating film IF3 are formed so as to be in contact with the uppermost layer of the multilayer wiring layer MWL3. Further, the upper inductor TL (coiled CL1b) that is a component of the transformer TR1 is formed so as to be in contact with the uppermost layer of the multilayer wiring layer MWL3.

Further, an inorganic insulating film 10c is formed on the wiring including the pad formed so as to be in contact with the uppermost layer of the multilayer wiring layer MWL3, on the upper inductor TL and on the insulating film IF3. However, as shown in FIG. 12, in the realization mode, no organic insulating film is formed on the inorganic insulating film 10c, and the entire upper surface of the inorganic insulating film 10c is in direct contact with the mold resin MR. Here, the inorganic insulating film 10c is formed of a silicon nitride film.

As shown in FIG. 12, the semiconductor chip CHP3 includes the upper inductor TL and the lower inductor BL, which are components of the transformer that performs non-contact communication between different potentials. In this case, the upper inductor TL is electrically connected to the wiring present in the multilayer wiring layer MWL2 formed in the semiconductor chip CHP2, and the second potential, which is a reference potential of about 800 V, is applied to the upper inductor TL. Specifically, the semiconductor device in the realization mode includes the semiconductor chip CHP2 including the circuit (second circuit) that applies the second potential to the upper inductor TL. The upper inductor TL formed in the semiconductor chip CHP3 is electrically connected to the circuit formed in the semiconductor chip CHP2 via the bonding wire W2 which is an exemplary conductive member. Accordingly, the second potential outputted from the circuit formed in the semiconductor chip CHP2 is applied to the upper inductor TL.

The lower inductor BL is electrically connected to the wiring present in the multilayer wiring layer MWL1 formed in the semiconductor chip CHP1, and the first potential, which is a reference potential of about 0 V, is applied to the lower inductor BL. Specifically, the semiconductor device in the realization mode includes the semiconductor chip CHP1 including the circuit (first circuit) that applies the first potential to the lower inductor BL. The lower inductor BL formed in the semiconductor chip CHP3 is electrically connected to the circuit formed in the semiconductor chip CHP1 via a bonding wire W1 which is an exemplary conductive member. Accordingly, the first potential outputted from the circuit formed in the semiconductor chip CHP1 is applied to the lower inductor BL.

Here, the upper inductor TL is formed so as to be magnetically connectable to the lower inductor BL to which the first potential different from the second potential is applied in the thickness direction of the semiconductor chip CHP3. Specifically, the upper inductor TL is formed in contact with the uppermost layer of the multilayer wiring layer MWL3, while the lower inductor BL is formed in the multilayer wiring layer MWL3. Thus, the upper inductor TL and the lower inductor BL are configured to be magnetically connectable to each other.

As shown in FIG. 12, the semiconductor chip CHP1, the semiconductor chip CHP2, and the semiconductor chip CHP3 configured as described above are sealed with, for example, the mold resin MR made of an epoxy resin. In other words, the semiconductor chip CHP1, the semiconductor chip CHP2, and the semiconductor chip CHP3 are covered with the mold resin MR. In this way, the semiconductor device of the three-chip configuration in the realization mode is configured.

In summary, the semiconductor device of the three-chip configuration in the realization mode includes the semiconductor chip CHP1 including the first circuit configured to supply the first potential to the lower inductor BL, the semiconductor chip CHP2 including the second circuit configured to supply the second potential to the upper inductor TL, and the semiconductor chip CHP3 including the lower inductor BL and the upper inductor TL. Here, the semiconductor chip CHP1 includes the transistor Q1 which is a component of the first circuit, the multilayer wiring layer MWL1 having the multilayer wiring electrically connected to the transistor Q1, the inorganic insulating film 10a made of a silicon nitride film formed so as to cover the multilayer wiring layer MWL1, and the organic insulating film 20a made of a polyimide resin film formed so as to cover the inorganic insulating film 10a. Further, the semiconductor chip CHP2 includes the transistor Q2 which is a component of the second circuit, the multilayer wiring layer MWL2 having the multilayer wiring electrically connected to the transistor Q2, the inorganic insulating film 10b made of a silicon nitride film formed so as to cover the multilayer wiring layer MWL2, and the organic insulating film 20b made of a polyimide resin film formed so as to cover the inorganic insulating film 10b. On the other hand, the semiconductor chip CHP3 includes the lower inductor BL formed in the multilayer wiring layer MWL3, the upper inductor TL formed so as to be in contact with the uppermost layer of the multilayer wiring layer MWL3, and the inorganic insulating film 10c made of a silicon nitride film formed so as to cover the upper inductor TL. As shown in FIG. 12, the semiconductor chip CHP1, the semiconductor chip CHP2, and the semiconductor chip CHP3 are sealed with the mold resin MR made of, for example, an epoxy resin. Consequently, the organic insulating film 20a and the mold resin MR are in direct contact with each other in the semiconductor chip CHP1, and the organic insulating film 20b and the mold resin MR are in direct contact with each other in the semiconductor chip CHP2. In contrast, the inorganic insulating film 10c and the mold resin MR are in direct contact with each other in the semiconductor chip CHP3.

### Features in Realization Mode

The feature points in the realization mode will be explained.

A feature point of the realization mode of the present second embodiment is that, for example, as shown in FIG. 12, in the “transformer chip” (semiconductor chip CHP3), a polyimide resin film is not formed on the inorganic insulating film 10c, and the inorganic insulating film 10c is in direct contact with the mold resin MR.

As a result, since the polyimide resin film having high hygroscopic property, which is likely to cause “creeping discharge”, is not formed in the “transformer chip”, generation of “creeping discharge” can be suppressed. Therefore, the feature point can improve the breakdown voltage of the semiconductor device.

Here, as described above, the polyimide resin film has a function of preventing “filler attack” caused by the filler contained in the mold resin MR. In this regard, when the feature point in the realization mode is adopted, since the polyimide resin film is not formed in the “transformer chip”, it is considered that “filler attack” from the mold resin MR is feared. In this regard, the wiring that is susceptible to adverse effects from the “filler attack” is a fine wiring, but the “transformer chip” is not formed with a fine wiring because only the transformer is formed. In other words, the spiral wiring configuring the upper inductor TL is made of a wide wiring in order to reduce the parasitic resistance. That is, the width of the spiral wiring configuring the upper inductor TL is greater than the width of the fine wiring formed in the semiconductor chip CHP1 or the semiconductor chip CHP2, and such a wide wiring is less susceptible to “filler attack”.

Therefore, as in the realization mode of the present second embodiment, even if the polyimide resin film is not formed, adverse effects caused by the “filler attack” caused by the crushing fillers contained in the mold resin MR are small. Further, for example, a “filler attack” can be suppressed by using, as the filler contained in the mold resin, not a sharp crushing filler but a blunt spherical filler. In this way, in the three-chip configuration, since the fine wiring as formed in the semiconductor chip CHP1 or the semiconductor chip CHP2 is not formed in the “transformer chip”, it is not problematic that the polyimide resin film is not formed.

As described above, according to the realization mode of the present second embodiment, it is not necessary to consider the “filler attack”, and the polyimide resin film can be removed from the “transformer chip”. As a result, according to the realization mode, since the polyimide resin film having high hygroscopic property, which is likely to cause “creeping discharge”, is not formed in the “transformer chip”, generation of “creeping discharge” can be suppressed. Consequently, the present second embodiment can improve the breakdown voltage of semiconductor device can.

### First Modified Example in Second Embodiment

In the present first modified example, in addition to the idea based on the above-described first knowledge that “creeping discharge” is more likely to occur in a film having a higher humidity, an example based on the above-described second knowledge that “creeping discharge” is more likely to occur in an insulating film having a higher dielectric constant will be described.

In the present first modified example, for example, in FIG. 12, the inorganic insulating film 10c formed in the “transformer chip” (semiconductor chip CHP3) is not formed of a silicon nitride film, but is formed of a film having a dielectric constant (relative dielectric constant) smaller than that of a silicon nitride film. Thus, the present first modified example can suppress the generation of “creeping discharge” from the above-described second knowledge.

Specifically, in the present first modified example, for example, a silicon oxide film or a silicon oxynitride film is used as a film having a dielectric constant (relative dielectric constant) smaller than that of a silicon nitride film. Here, the dielectric constant (relative dielectric constant) of silicon nitride is “7” and the hygroscopic property of silicon nitride is “approximately 0%”, while the dielectric constant (relative dielectric constant) of silicon oxide is “4.5” and the hygroscopic property of silicon oxide is “approximately 0%”, and the dielectric constant (relative dielectric constant) of silicon oxynitride is “5.7” and the hygroscopic property of silicon oxynitride is “approximately 0%”.

Therefore, the use of a silicon oxide film or a silicon oxynitride film having a dielectric constant smaller than that of silicon nitride instead of a silicon nitride film having a higher dielectric constant (relative dielectric constant) as the inorganic insulating film 10c can suppress the generation of “creeping discharges”.

### Second Modified Example

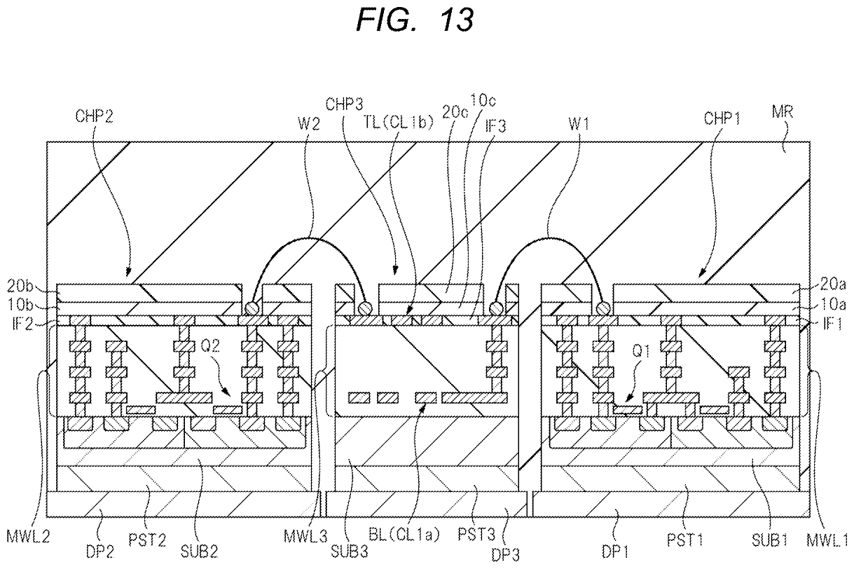

In the present second modified example, for example, in FIG. 13, the inorganic insulating film 10c is formed of a film having a dielectric constant smaller than that of the silicon nitride film, and an organic insulating film 20c is interposed between the inorganic insulating film 10c and the mold resin MR.

Here, for example, the inorganic insulating film 10c can be formed of a silicon oxide film or a silicon oxynitride film. On the other hand, in the present second modified example, since at least the inorganic insulating film 10c is formed of a film having a dielectric constant smaller than that of the silicon nitride film, generation of “creeping discharge” can be suppressed as compared with the case where the inorganic insulating film 10c is formed of the silicon nitride film even if the organic insulating film 20c is interposed between the inorganic insulating film 10c and the mold resin MR.

That is, for example, even if the organic insulating film 20c is formed of a polyimide resin film, if the inorganic insulating film 10c is formed of a film having a dielectric constant smaller than that of the silicon nitride film, generation of “creeping discharge” can be suppressed.

However, from the viewpoint of suppressing the generation of “creeping discharge”, it is desirable that the organic insulating film 20c interposed between the inorganic insulating film 10c and the mold resin MR is formed of a film having lower hygroscopic property than the polyimide resin film. Examples of the film having lower hygroscopic property than the polyimide resin film include a fluorinated polyimide resin film and a benzocyclobutene film.

Here, the dielectric constant (relative dielectric constant) of the polyimide resin is “7” and the hygroscopic property of the polyimide resin is “1.20”, while the dielectric constant (relative dielectric constant) of the fluorinated polyimide resin is “2.7” and the hygroscopic property of the fluorinated polyimide resin is “0.30”, the dielectric constant (relative dielectric constant) of the benzocyclobutene is “2.7” and the hygroscopic property of the benzocyclobutene is “0.20”. Therefore, as the inorganic insulating film 10c, a silicon oxide film or a silicon oxynitride film having a dielectric constant (relative dielectric constant) smaller than that of silicon nitride is used instead of a silicon nitride film having a high dielectric constant (relative dielectric constant), and as the organic insulating film 20c, a fluorinated polyimide resin film or a benzocyclobutene film having a hygroscopic property lower than that of a polyimide resin film is used instead of a polyimide resin film having a high hygroscopic property, whereby generation of “creeping discharge” can be suppressed.

The invention made by the present inventor has been described above in detail based on the embodiment, but the present invention is not limited to the embodiment described above, and it is needless to say that various modifications can be made without departing from the gist thereof.

For example, in the above-described embodiment, the “transformer communication” between inductors has been described as an example, but the basic idea in the above-described embodiment is not limited to this, and can be applied to the “inter-electrode communication” of a capacitor. In the capacitor, the lower electrode is disposed in the multilayer wiring layer MWL1 instead of the lower inductor BL, and the upper electrode is disposed on the multilayer wiring layer MWL1 instead of the upper inductor TL. Each of the upper electrode and the lower electrode is formed of a plate-shaped wiring. The upper electrode and the lower electrode are formed so as to be capacitively connectable to each other. The potential applied to the upper electrode is the same as the potential applied to the upper inductor TL. The potential applied to the lower electrode is the same as the potential applied to the lower layer inductor BL. The relationship between the upper electrode and the other member is the same as the relationship between the upper inductor TL and the other member. The relationship between the lower electrode and the other member is the same as the relationship between the lower inductor BL and the other member.

What is claimed is:

1. A semiconductor device comprising:
a semiconductor substrate;
a multilayer wiring layer formed on the semiconductor substrate;
a first wiring formed on the multilayer wiring layer and configured to be applied with a first potential;
an inductor formed on the multilayer wiring layer and configured to be applied with a second potential different from the first potential;
an inorganic insulating film formed on the multilayer wiring layer, the first wiring and the inductor; and
an organic insulating film formed on the inorganic insulating film and disposed so as to cover the inorganic insulating film located between the first wiring and the inductor in plan view,
wherein between the first wiring and the inductor, an opening portion exposing a part of an upper surface of the inorganic insulating film is formed in the organic insulating film.

2. The semiconductor device according to claim 1,
wherein the opening portion is formed so as to surround the inductor in plan view.

3. The semiconductor device according to claim 1,
wherein the opening portion is configured by:
a first opening portion extending in a first direction;
a second opening portion extending in a second direction intersecting with the first direction;
a third opening portion extending in the first direction and facing the first opening portion; and
a fourth opening portion extending in the second direction and facing the second opening portion,
wherein the inductor is disposed between the first opening portion and the third opening portion in plan view,
wherein the inductor is disposed between the second opening portion and the fourth opening portion in plan view,
wherein the first opening portion and the second opening portion are spaced apart from each other in plan view,
wherein the first opening portion and the fourth opening portion are spaced apart from each other in plan view,
wherein the third opening portion and the second opening portion are spaced apart from each other in plan view, and
wherein the third opening portion and the fourth opening portion are spaced apart from each other in plan view,

4. The semiconductor device according to claim 1,
wherein the opening portion is formed so as to include the inductor.

5. The semiconductor device according to claim 4,
wherein the opening portion is formed so as to include a part of the first wiring.

6. The semiconductor device according to claim 1,
wherein the semiconductor device comprises:
a first semiconductor chip including:
the first wiring;
a circuit electrically connected to the first wiring;
the inductor; and
the organic insulating film; and
a second semiconductor chip including a circuit configured to supply the second potential to the inductor.

7. The semiconductor device according to claim 1,
wherein the inductor includes:
a first pad connectable to a first bonding wire; and
a second wiring connected to the first pad, and
wherein a width of the second wiring is greater than a width of the first wiring.

8. The semiconductor device according to claim 1,
wherein the first wiring is disposed so as to be in contact with an uppermost layer of the multilayer wiring layer, and
wherein the inductor is disposed so as to be in contact with the uppermost layer.

9. The semiconductor device according to claim 1, comprising:
a pad opening portion formed to penetrate through the organic insulating film and the inorganic insulating film in order to expose a pad connectable to a bonding wire,
wherein the opening portion is different from the pad opening portion.

10. A semiconductor device comprising:
a semiconductor substrate;
a multilayer wiring layer formed on the semiconductor substrate;
a first inductor formed in the multilayer wiring layer and configured to be applied with a first potential;
a second inductor formed on the multilayer wiring layer, configured to be applied with a second potential different from the first potential and configured to be magnetically connectable to the first inductor;
an inorganic insulating film formed on the second inductor; and
a mold resin formed so as to cover the inorganic insulating film.

11. The semiconductor device according to claim 10,
wherein an upper surface of the inorganic insulating film is in direct contact with the mold resin.

12. The semiconductor device according to claim 10,
wherein the inorganic insulating film has a dielectric constant smaller than a dielectric constant of a silicon nitride film, and
wherein an organic insulating film is interposed between the inorganic insulating film and the mold resin.

13. The semiconductor device according to claim 12,
wherein the organic insulating film is a polyimide resin film, a fluorinated polyimide resin film, or a benzocyclobutene film.

14. The semiconductor device according to claim 11,
wherein the mold resin includes a spherical filler.

15. The semiconductor device according to claim 11,
wherein the semiconductor device comprises:
a first semiconductor chip including a first circuit configured to supply the first potential to the first inductor;
a second semiconductor chip including a second circuit configured to supply the second potential to the second inductor;
a third semiconductor chip including the first inductor, the second inductor and the inorganic insulating film.

16. The semiconductor device according to claim 15,
wherein the first semiconductor chip includes:
a first transistor being a component of the first circuit;
a first multilayer wiring electrically connected to the first transistor;
a first silicon nitride film formed so as to cover the first multilayer wiring; and
a first organic insulating film formed so as to cover the first silicon nitride film, and
wherein the second semiconductor chip includes:
a second transistor being a component of the second circuit;
a second multilayer wiring electrically connected to the second transistor;
a second silicon nitride film formed so as to cover the second multilayer wiring; and
a second organic insulating film formed so as to cover the second silicon nitride film.

17. A semiconductor device comprising:
a semiconductor substrate;
a multilayer wiring layer formed on the semiconductor substrate;
a first wiring formed on the multilayer wiring layer and configured to be applied with a first potential;
a first electrode formed on the multilayer wiring layer and configured to be applied with a second potential different from the first potential, the first electrode being a component of a capacitor;
an inorganic insulating film formed on the multilayer wiring layer, the first wiring and the first electrode; and
an organic insulating film formed on the inorganic insulating film and disposed so as to cover the inorganic insulating film located between the first wiring and the first electrode in plan view,
wherein between the first wiring and the first electrode, an opening portion exposing a part of an upper surface of the inorganic insulating film is formed in the organic insulating film.

18. A semiconductor device comprising:
a semiconductor substrate;
a multilayer wiring layer formed on the semiconductor substrate;
a lower electrode formed in the multilayer wiring layer and configured to be applied with a first potential;
an upper electrode formed on the multilayer wiring layer, configured to be applied with a second potential different from the first potential and configured to be capacitively connectable to the lower electrode;
an inorganic insulating film formed on the upper electrode; and
a mold resin formed so as to cover the inorganic insulating film.

19. The semiconductor device according to claim 18,
wherein an upper surface of the inorganic insulating film is in direct contact with the mold resin.

20. The semiconductor device according to claim 18,
wherein the inorganic insulating film has a dielectric constant smaller than a dielectric constant of a silicon nitride film, and
wherein an organic insulating film is interposed between the inorganic insulating film and the mold resin.
